(19) United States
(12) Patent Application Publication
(10) Pub. No.: US 2024/0105896 A1
(43) Pub. Date: Mar. 28, 2024

(54) DISPLAY DEVICE

(71) Applicant: Samsung Display Co., Ltd., Yongin-si (KR)

(72) Inventor: CHANG-YEOL LEE, Yongin-si (KR)

(21) Appl. No.: 18/213,900

(22) Filed: Jun. 26, 2023

(30) Foreign Application Priority Data
Sep. 26, 2022 (KR) 10-2022-0121457

(51) Int. Cl. H01L 33/62; H01L 25/16

(52) U.S. Cl. CPC H01L 33/62; H01L 25/167

(57) ABSTRACT

A display device includes a substrate including a display area and a peripheral area, a light emitting device disposed in a display area on a substrate, a transfer line disposed on a substrate, extending in a first direction, and including a plurality of identification parts arranged along a first direction and at least one connection part disposed between adjacent identification parts, and identification marks, each of the identification marks is disposed in an area corresponding to each identification part of a transfer line adjacent to the each identification part of the transfer line, and the each of identification marks is disposed on an imaginary line extending from a center point of a corresponding identification part in a direction intersecting the first direction in a plan view.

This application claims priority to Korean Patent Application No. 10-2022-0121457 filed on Sep. 26, 2022, and all the benefits accruing therefrom under 35 U.S.C. § 119, the content of which in its entirety is herein incorporated by reference.

### BACKGROUND

### 1. Field

Embodiments of the inventive concept relate to a display device.

### 2. Description of the Related Art

As information technology develops, the importance of display devices, which are communication media between users and information, is being highlighted. Accordingly, the use of display devices such as liquid crystal display devices, organic light emitting display devices, plasma display devices, or the like is increasing.

A plurality of transfer lines may be disposed in the display device. When a driving defect of the display device occurs, it may be required to identify the order and/or position of the transfer lines in order to find the position where the defect occurs.

### SUMMARY

Embodiments provide a display device having a simplified structure and improved manufacturing process efficiency.

A display device according to an embodiment includes a substrate including a display area and a peripheral area, a light emitting device disposed in the display area on the substrate, a transfer line disposed on the substrate, extending in a first direction, and including a plurality of identification parts arranged along the first direction and at least one connection part disposed between adjacent identification parts, and a plurality of identification marks, each of the identification marks is disposed in an area corresponding to each identification part of the transfer line adjacent to the each identification part of the transfer line, and the each of the plurality of identification marks is disposed on an imaginary line extending from a center point of the corresponding identification part in a direction intersecting the first direction in a plan view.

In an embodiment, the imaginary line may extend from the center point of the identification part in a second direction perpendicular to the first direction, in a third direction inclined in a clockwise direction to the first direction and inclined in a counterclockwise direction to the second direction, in a fourth direction inclined in a clockwise direction to the third direction and inclined in a counterclockwise direction to the second direction, in a fifth direction inclined in a clockwise direction to the second direction, in a sixth direction inclined in a clockwise direction to the fifth direction, in a direction opposite to the first direction, in a direction opposite to the third direction, in a direction opposite to the fourth direction, in a direction opposite to the second direction, in a direction opposite to the fifth direction, or in a direction opposite to the sixth direction.

In an embodiment, an angle between the third direction and the first direction may be about 30 degrees.

In an embodiment, an angle between the fourth direction and the first direction may be about 60 degrees.

In an embodiment, an angle between the fifth direction and the second direction may be about 30 degrees.

In an embodiment, an angle between the sixth direction and the second direction may be about 60 degrees.

In an embodiment, the transfer line may include a first side extending in the first direction, and a second side extending in the first direction and facing the first side in the second direction, and the each of the plurality of identification marks may be disposed adjacent to the first side or the second side in a plan view.

In an embodiment, among the plurality of identification marks, an identification mark disposed on the imaginary line extending from the center point of the identification part in the direction opposite to the third direction, in the direction opposite to the fourth direction, in the direction opposite to the second direction, in the direction opposite to the fifth direction, or in the direction opposite to the sixth direction may be disposed adjacent to the first side of the transfer line in a plan view.

In an embodiment, among the plurality of identification marks, an identification mark disposed on the imaginary line extending from the center point of the identification part in the second direction, in the third direction, in the fourth direction, in the fifth direction, or in the sixth direction may be disposed adjacent to the second side of the transfer line in a plan view.

In an embodiment, a planar shape of each of the plurality of identification marks may be a polygonal shape, a diamond shape, a circular shape, a track shape, an ellipse shape, or an arrow shape.

In an embodiment, a planar shape of each of the plurality of identification parts may be a polygonal shape or a circular shape.

In an embodiment, a planar shape of the plurality of identification parts and a planar shape of the at least one connection part are different from each other.

In an embodiment, the display device may further include a transistor including an active pattern, a gate electrode, a source electrode, and a drain electrode sequentially disposed in the display area on the substrate, and the at least one identification marks may be disposed on the same layer as any one of the active pattern, the gate electrode, the source electrode, and the drain electrode.

In an embodiment, the transfer line may be connected to a data line providing a data voltage to a pixel structure disposed in the display area.

A display device according to another embodiment includes a substrate including a display area and a peripheral area, a light emitting device disposed in the display area on the substrate, a transfer line disposed on the substrate, extending in a first direction, and including a plurality of identification parts arranged along the first direction and at least one connection part disposed between adjacent identification parts, and a plurality of identification marks, each of the plurality of identification marks is disposed in an area corresponding to each identification part of the transfer line, the each of the plurality of identification marks overlaps the corresponding identification part in a plan view, the each of the plurality of identification parts is divided into a main area and a sub area by a reference line extending from a center point or the each of the identification parts in the first direction and an imaginary line extending from the center point or the each of the identification parts in a direction intersecting the first direction, and each of the plurality of identification marks covers one of the main area and the sub area of the corresponding identification part and exposes a remaining area.

In an embodiment, the imaginary line may extend from the center point of the identification part in a second direction perpendicular to the first direction, in a third direction inclined in a clockwise direction to the first direction and inclined in a counterclockwise direction to the second direction, in a fourth direction inclined in a clockwise direction to the third direction and inclined in a counterclockwise direction to the second direction, in a fifth direction inclined in a clockwise direction to the second direction, in a sixth direction inclined in a clockwise direction to the fifth direction, in a direction opposite to the first direction, in a direction opposite to the third direction, in a direction opposite to the fourth direction, in a direction opposite to the second direction, in a direction opposite to the fifth direction, or in a direction opposite to the sixth direction.

In an embodiment, an angle between the third direction and the first direction may be about 30 degrees.

In an embodiment, an angle between the fourth direction and the first direction may be about 60 degrees.

In an embodiment, an angle between the fifth direction and the second direction may be about 30 degrees.

In an embodiment, an angle between the sixth direction and the second direction may be about 60 degrees.

Therefore, the display device according to embodiments may include a transfer line and an identification mark. The identification mark may be disposed in an area corresponding to an identification part of the transfer line. For example, the identification mark may be disposed adjacent to the identification part and may be disposed to indicate a specific direction. Also, the identification mark may also overlap the identification part and cover only a specific area of the identification part.

Accordingly, an identification pattern for determining a position and/or order of the transfer line may be defined from the identification mark having a simple shape. Accordingly, without forming an additional pattern indicating the transfer line that includes numbers corresponding to the transfer line or changing a distance between the transfer lines, the position and/or order of the transfer line may be determined. Accordingly, a structure of the display device may be simplified, and efficiency of a manufacturing process of the display device may be increased.

It is to be understood that both the foregoing general description and the following detailed description are exemplary and explanatory and are intended to provide further explanation of the inventive concept as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a plan view enlarged an area ‘A’ of FIG. 1 according to an embodiment.

FIG. 3 is a cross-sectional view illustrating a cross section taken along line I-I′ of FIG. 1 and line II-II′ of FIG. 2 according to an embodiment.

FIG. 4 is a cross-sectional view illustrating a cross section taken along line I-I′ of FIG. 1 and line II-II′ of FIG. 2 according to another embodiment.

FIG. 5 is a cross-sectional view illustrating a cross section taken along line I-I′ of FIG. 1 and line II-II′ of FIG. 2 according to still another embodiment.

FIG. 6 is a cross-sectional view illustrating a cross section taken along line I-I′ of FIG. 1 and line II-II′ of FIG. 2 according to still another embodiment.

FIG. 7 is a plan view enlarged an area ‘A’ of FIG. 1 according to another embodiment.

FIG. 8 is a plan view enlarged an area ‘A’ of FIG. 1 according to still another embodiment.

FIG. 9 is a plan view enlarged an area ‘A’ of FIG. 1 according to still another embodiment.

### DETAILED DESCRIPTION

The inventive concept now will be described more fully hereinafter with reference to the accompanying drawings, in which various embodiments are shown. This inventive concept may, however, be embodied in many different forms, and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout.

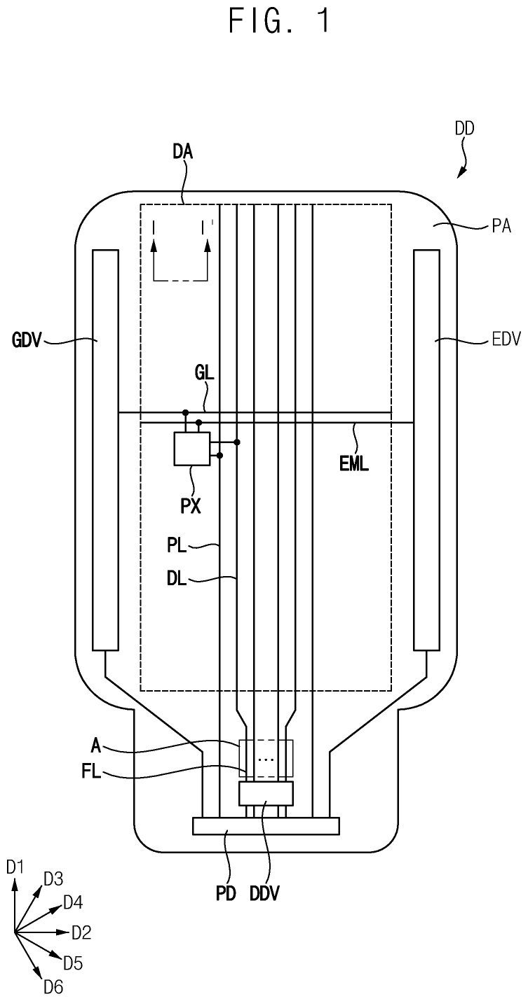

FIG. 1 is a plan view illustrating a display device according to an embodiment.

Referring to FIG. 1, the display device DD may include a display area DA and a peripheral area PA. In an embodiment, the peripheral area PA may be located around the display area DA. For example, the peripheral area PA may surround the display area DA.

In an embodiment, the display device DD may have a substantially rectangular shape in a plan view. For example, the display device DD may have a rectangular shape with rounded corners in a plan view. However, the present inventive concept is not necessarily limited thereto, and the display device DD may have various shapes in a plan view. For example, in a plan view, the display device DD may have a rectangular shape with vertical corners.

A plurality of pixels PX may be disposed in the display area DA, and an image may be displayed through the plurality of pixels PX in the display area DA. Each of the plurality of pixels PX may include a driving device (e.g., a transistor) and a light emitting device (e.g., an organic light emitting diode) connected to the driving device. The light emitting device may emit light in response to a signal and/or voltage received from the driving device. For example, the driving device may provide a driving current to the light emitting device, and the light emitting device may generate light having a luminance corresponding to the driving current. The plurality of pixels PX may be generally disposed in the display area DA. For example, the plurality of pixels PX may be arranged in a matrix form in the display area DA.

A driver for driving the plurality of pixels PX may be disposed in the peripheral area PA. For example, the driver may include a gate driver GDV, a data driver DDV, an emission driver EDV, and a pad part PD. The driver may provide the signal and/or the voltage to the pixel PX.

The display device DD may include a plurality of data lines DL, a plurality of gate lines GL, a plurality of emission control lines EML, a plurality of driving voltage lines PL, and a plurality of transfer lines FL that transfers the signal and/or the voltage to the pixel structure.

In an embodiment, the plurality of transfer lines FL may be electrically connected to the data driver DDV and the plurality of data lines DL, and may extend along a first direction D1. In other words, each of the plurality of transfer lines FL may receive a data voltage from the data driver DDV and provide the data voltage to a data line DL. A plurality of transfer lines FL may be disposed between the display area and the data driver DDV to connect the data driver DDV to a plurality of data lines DL. For example, each of the plurality of transfer lines FL may be a fan-out line electrically connecting the data driver DDV and the data line DL. However, the present inventive concept is not necessarily limited thereto, and each of the plurality of transfer lines FL may include various lines such as a power transfer line for providing a power supply voltage to the light emitting device disposed in the display area DA.

In an embodiment, the plurality of gate lines GL may be electrically connected to the gate driver GDV and may extend along a second direction D2 intersecting the first direction D1. Each of the plurality of gate lines GL may receive a gate signal from the gate driver GDV and provide the gate signal to the plurality of pixels PX.

The plurality of emission control lines EML may be connected to the emission driver EDV and may extend along the second direction D2. Each of the plurality of emission control lines EML may receive an emission control signal from the emission driver EDV and provide the emission control signal to pixels PX connected to the emission control line. For example, an active period of the emission control signal may be an emission period of the display device DD and an inactive period of the emission control signal may be a non-emission period of the display device DD.

The plurality of driving voltage lines PL may be connected to the pad part PD and may extend along the first direction D1. The plurality of driving voltage lines PL may receive a high power voltage from the pad part PD and provide the high power voltage to the plurality of pixels PX.

The gate driver GDV may generate the gate signal by receiving a voltage from the pad part PD. The data driver DDV may generate the data voltage corresponding to the emission period and the non-emission period of the display device DD. The emission driver EDV may generate the emission control signal by receiving a voltage from the pad part PD. The pad part PD may be electrically connected to an external device to provide voltages to each of the gate driver GDV, the emission driver EDV, and the driving voltage line PL.

Meanwhile, although the gate driver GDV is illustrated as being disposed in the peripheral area PA adjacent to a left side of the display area DA and the emission driver EDV is illustrated as being disposed in the peripheral area PA adjacent to the right side of the display area DA in FIG. 1, the present inventive concept is not necessarily limited thereto. For example, the gate driver GDV and the emission driver EDV may be disposed at different locations in the peripheral area PA.

In addition, although the data driver DDV is illustrated as being mounted in the peripheral area PA of the display device DD in FIG. 1, the present inventive concept is not necessarily limited thereto. For example, a separate flexible printed circuit board (FPCB) may be disposed in the peripheral area PA, and the data driver DDV may be disposed on the flexible printed circuit board. In this case, the pad part PD may be electrically connected to the flexible printed circuit board.

Meanwhile, in this specification, a plane may be defined by the first direction D1 and the second direction D2 intersecting the first direction D1. For example, the second direction D2 may be perpendicular to the first direction D1 in a plan view.

In addition, in this specification, each of a third direction D3, a fourth direction D4, a fifth direction D5, and the sixth direction D6 may be an inclined direction to the first direction D1 and the second direction D2.

In other words, the third direction D3 may be a direction inclined in a clockwise direction to the first direction D1 and inclined in a counterclockwise direction to the second direction D2. Also, the fourth direction D4 may be a direction inclined in a clockwise direction to the third direction D3 and inclined in a counterclockwise direction to the second direction D2. Also, the fifth direction D5 may be a direction inclined in a clockwise direction to the second direction D2. Also, the sixth direction D6 may be a direction inclined in a clockwise direction to the fifth direction D5.

In an embodiment, a first angle between the third direction D3 and the first direction D1 may be about 30 degrees. In other words, the third direction D3 may be a direction inclined by about 30 degrees in a clockwise direction to the first direction D1. Also, a second angle between the fourth direction D4 and the first direction D1 may be about 60 degrees. In other words, the fourth direction D4 may be a direction inclined by about 30 degrees in a clockwise direction to the third direction D3.

Also, a third angle between the fifth direction D5 and the second direction D2 may be about 30 degrees. In other words, the fifth direction D5 may be a direction inclined by about 30 degrees in a clockwise direction to the second direction D2. Also, a fourth angle between the sixth direction D6 and the second direction D2 may be about 60 degrees. In other words, the sixth direction D6 may be a direction inclined by about 30 degrees in a clockwise direction to the fifth direction D5.

However, the present inventive concept is not necessarily limited thereto, and angles formed by the first to sixth directions D1, D2, D3, D4, D5, and D6 in a plan view may be variously changed.

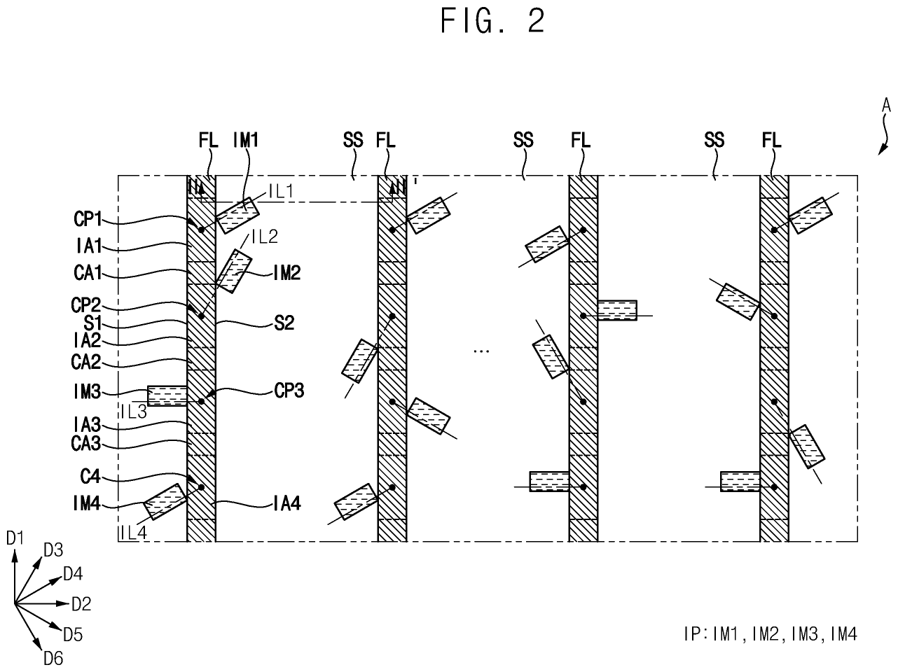

FIG. 2 is a plan view enlarged an area ‘A’ of FIG. 1 according to an embodiment.

Referring to FIGS. 1 and 2, the display device DD according to an embodiment may include a plurality of transfer lines FL and a plurality of separation spaces SS.

The plurality of transfer lines FL may be disposed in the peripheral area PA. The plurality of transfer lines FL may extend in the first direction D1. Also, the plurality of transfer lines FL may be repeatedly disposed along the second direction D2 intersecting the first direction D1. Each of the plurality of separation spaces SS may be formed between at least two adjacent transfer lines FL.

Each of the plurality of transfer lines FL may have a first side S1 and a second side S2. Each of the first side S1 and the second side S2 may extend in the first direction D1. The first side S1 and the second side S2 may face each other in the second direction D2. A shape of the first side S1 and a shape of the second side S2 may be symmetrical to each other with a line extending parallel to the first direction D1 as a line of symmetry.

Each of the transfer line FL may include a plurality of identification parts and at least one connection part disposed between adjacent identification parts. The plurality of identification parts may be areas in which identification marks for identifying a position and/or order of each of the plurality of transfer lines FL are disposed. In other words, one of the identification marks may be disposed in an area correspond to one of the identification parts included in the transfer line FL. For example, the identification marks may be disposed adjacent to the corresponding identification parts, respectively. The connection part may be an area disposed between the adjacent identification parts.

In an embodiment, the transfer line FL may include first to fourth identification parts IA1, IA2, IA3, and IA4 and first to third connection parts CA1, CA2, and CA3 alternatingly disposed along the first direction D1.

Each of the first to fourth identification parts IA1, IA2, IA3, and IA4 may be spaced apart from each other with one of the first to third connection parts CA1, CA2, and CA3 disposed therebetween. For example, the second identification part IA2 may be spaced apart from the first identification part IA1 in the first direction D1 with the first connection part CA1 disposed therebetween, the third identification part IA3 may be spaced apart from the second identification part IA2 in the first direction D1, and the fourth identification part IA4 may be spaced apart from the third identification part IA3 in the first direction D1 with the second connection part CA2 disposed therebetween. In other words, the first to fourth identification parts IA1, IA2, IA3, and IA4 may be sequentially arranged along the first direction D1.

In an embodiment, a planar shape of each of the first to fourth identification parts IA1, IA2, IA3, and IA4 may be a rectangular shape. However, the present inventive concept is not necessarily limited thereto. In another embodiment, the planar shape of each of the first to fourth identification parts IA1, IA2, IA3, and IA4 may be a polygonal shape or a circular shape. For example, a planar shape of each of the first to fourth identification parts IA1, IA2, IA3, and IA4 may be a hexagonal shape, an octagonal shape, a decagonal shape, or a circular shape.

In an embodiment, each of the identification parts may have a center point. Each of the identification parts may be point symmetric to the center point of each of the identification parts in a plan view.

For example, the first identification part IA1 may be point symmetric to the first center point CP1 of the first identification part IA1. The second identification part IA2 may be point symmetric to the second center point CP2 of the second identification part IA2. The third identification part IA3 may be point symmetric to the third center point CP3 of the third identification part IA3. The fourth identification part IA4 may be point symmetric to the fourth central point CP4 of the fourth identification part IA4.

Each of the first to third connection parts CA1, CA2, and CA3 may be disposed between adjacent identification parts IA1, IA2, IA3, and IA4. For example, the first connection part CA1 may be disposed between the first identification part IA1 and the second identification part IA2, the second connection part CA2 may be disposed between the second identification part IA2 and the third identification part IA3, and the third connection part CA3 may be disposed between the third identification part IA3 and the fourth identification part IA4.

In an embodiment, each of the first to fourth identification parts IA1, IA2, IA3, and IA4 may have a rectangular shape in a plan view, and each of the first to third connection parts CA1, CA2, and CA3 may also have a rectangular shape in a plan view. However, the present inventive concept is not necessarily limited thereto.

In an embodiment, first to fourth identification marks IM1, IM2, IM3, and IM4 may be disposed adjacent to the transfer line FL. For example, the first to fourth identification marks IM1, IM2, IM3, and IM4 may be disposed adjacent to the first side S1 of the transfer line FL or the second side S2 of the transfer line FL.

In an embodiment, a planar shape of each of the first to fourth identification marks IM1, IM2, IM3, and IM4 may be a rectangular shape. However, the present inventive concept is not necessarily limited thereto. For example, the planar shape of each of the first to fourth identification marks IM1, IM2, IM3, and IM4 may be a polygonal shape, a diamond shape, a circular shape, a track shape, an ellipse shape, or an arrow shape.

Each of the first to fourth identification marks IM1, IM2, IM3, and IM4 may be disposed adjacent to one of the first to fourth identification parts IA1, IA2, IA3, and IA4 of the transfer line FL. For example, one identification part of the transfer line FL and one identification mark disposed adjacent to the one identification part of the transfer line FL may correspond to each other.

For example, the first identification mark IM1 may correspond to the first identification part IA1, the second identification mark IM2 may correspond to the second identification part IA2, the third identification mark IM3 may correspond to the third identification part IA3, and the fourth identification mark IM4 may correspond to the fourth identification part IA4.

In other words, the first identification mark IM1 may be disposed adjacent to the first identification part IA1, the second identification mark IM2 may be disposed adjacent to the second identification part IA2, the third identification mark IM3 may be disposed adjacent to the third identification part IA3, and the fourth identification mark IM4 may be disposed adjacent to the fourth identification part IA4.

The first to fourth identification marks IM1, IM2, IM3, and IM4 disposed adjacent to one transfer line FL may be defined as one identification pattern IP. In other words, the one identification pattern IP may correspond to the one transfer line FL, and the identification pattern IP may include the first to fourth identification marks IM1, IM2, IM3, and IM4 disposed adjacent to the corresponding one transfer line FL. The position and/or order of the transfer line FL may be identified from the identification pattern IP.

In an embodiment, each of the first to fourth identification marks IM1, IM2, IM3, and IM4 may be disposed on an imaginary line extending in a specific direction from the center point of the corresponding identification part in a plan view.

For example, the first identification mark IM1 may be disposed on a first imaginary line IL1 extending in a specific direction from the first center point CP1 of the first identification part IA1. The second identification mark IM2 may be disposed on a second imaginary line IL2 extending in a specific direction from the second center point CP2 of the second identification part IA2. The third identification mark IM3 may be disposed on a third imaginary line IL3 extending in a specific direction from the third center point CP3 of the third identification part IA3. The fourth identification mark IM4 may be disposed on a fourth imaginary line IL4 extending in a specific direction from the fourth center point CP4 of the fourth identification part IA4.

Accordingly, the first identification mark IM1 may indicate a direction in which the first imaginary line IL1 extends from the first center point CP1. Also, the second identification mark IM2 may indicate a direction in which the second imaginary line IL2 extends from the second center point CP2. Also, the third identification mark IM3 may indicate a direction in which the third imaginary line IL3 extends from the third center point CP3. Also, the fourth identification mark IM4 may indicate a direction in which the fourth imaginary line IL4 extends from the fourth center point CP4.

In an embodiment, each of the first to fourth imaginary lines ILL IL2, IL3, and IL4 may extend from the corresponding center point in a direction parallel to the first direction D1, in a direction parallel to the second direction D2, or in an inclined direction to the first direction D1 and the second direction D2.

For example, each of the first to fourth imaginary lines ILL IL2, IL3, and IL4 may extend from the corresponding center point in the second direction D2, in the third direction D3, in the fourth direction D4, in the fifth direction D5, in the sixth direction D6, a direction opposite to the second direction D2, a direction opposite to the third direction D3, a direction opposite to the fourth direction D4, a direction opposite to the fifth direction D5, or a direction opposite to the sixth direction D6.

Accordingly, the identification mark disposed on the imaginary line extending in the second direction D2 from the corresponding center point may indicate the second direction D2. Also, the identification mark disposed on the imaginary line extending in the third direction D3 from the corresponding center point may indicate the third direction D3. Also, the identification mark disposed on the imaginary line extending in the fourth direction D4 from the corresponding center point may indicate the fourth direction D4. Also, the identification mark disposed on the imaginary line extending in the fifth direction D5 from the corresponding center point may indicate the fifth direction D5. Also, the identification mark disposed on the imaginary line extending in the sixth direction D6 from the corresponding center point may indicate the sixth direction D6.

In addition, the identification mark disposed on the imaginary line extending in the direction opposite to the third direction D3 from the corresponding center point may indicate the direction opposite to the third direction D3. Also, the identification mark disposed on an imaginary line extending in the direction opposite to the fourth direction D4 from the corresponding center point may indicate the direction opposite to the fourth direction D4. Also, the identification mark disposed on an imaginary line extending in the direction opposite to the second direction D2 from the corresponding center point may indicate the direction opposite to the second direction D2. Also, the identification mark disposed on an imaginary line extending in the direction opposite to the fifth direction D5 from the corresponding center point may indicate the direction opposite to the fifth direction D5. Also, the identification mark disposed on an imaginary line extending in the direction opposite to the sixth direction D6 from the corresponding center point may indicate the direction opposite to the sixth direction D6.

In an embodiment, among the first to fourth identification marks IM1, IM2, IM3, and IM4, the identification mark disposed on the imaginary line extending from the corresponding center point in the direction opposite to the third direction D3, in the direction opposite to the fourth direction D4, in the direction opposite to the second direction D2, in the direction opposite to the fifth direction D5, or in the direction opposite to the sixth direction D6 may be disposed adjacent to the first side S1 of the transfer line FL in a plan view.

On the other hand, among the first to fourth identification marks IM1, IM2, IM3, and IM4, the identification mark disposed on the imaginary line extending from the corresponding center point in the second direction D2, in the third direction D3, in the fourth direction D4, in the fifth direction in D5, or in the sixth direction D6 may be disposed adjacent to the second side S2 of the transfer line FL in a plan view.

Meanwhile, directions in which each of the first to fourth imaginary lines ILL IL2, IL3, and IL4 extends from the corresponding center point may be respectively determined for each transfer line FL.

In an embodiment, each of the first to fourth identification marks IM1, IM2, IM3, and IM4 may be identified with one of integers from ‘0’ to ‘9’ according to a direction they indicate, respectively.

For example, when the identification mark indicates the third direction D3, it may be identified as the number ‘1’. When the identification mark indicates the fourth direction D4, it may be identified as the number ‘2’. When the identification mark indicates the second direction D2, it may be identified as the number ‘3’. When the identification mark indicates the fifth direction D5, it may be identified as the number ‘4’. When the identification mark indicates the sixth direction D6, it may be identified as the number ‘5’.

In addition, when the identification mark indicates the direction opposite to the first direction D1, it may be identified as the number ‘6’. When the identification mark indicates the direction opposite to the third direction D3, it may be identified as the number ‘7’. When the identification mark indicates the direction opposite to the fourth direction D4, it may be identified as the number ‘8’. When the identification mark indicates the direction opposite to the second direction D2, it may be identified as the number ‘9’. When the identification mark indicates the direction opposite to the fifth direction D5, it may be identified as the number ‘0’. In addition, when the identification mark indicates the direction opposite to the sixth direction D6, it may be identified as the number ‘6’.

Accordingly, the identification pattern IP corresponding to each transfer lines FL may be used as an identification number of the position and/or order of the transfer line FL.

Hereinafter, a method of deriving the identification number will be described in more detail with respect to the transfer line FL disposed at the leftmost of the transfer lines shown in FIG. 2 as an example.

In an embodiment, the first identification mark IM1 may be disposed on the first imaginary line IL1 extending from the first center point CP1 of the first identification part IA1 in the fourth direction D4. Accordingly, the first identification mark IM1 may indicate the fourth direction D4. Accordingly, the first identification mark IM1 may be identified as the number ‘2’.

In an embodiment, the second identification mark IM2 may be disposed on the second imaginary line IL2 extending from the second center point CP2 of the second identification part IA2 in the third direction D3. Accordingly, the second identification mark IM2 may indicate the third direction D3. Accordingly, the second identification mark IM2 may be identified as the number ‘1’.

In an embodiment, the third identification mark IM3 may be disposed on the third imaginary line IL3 extending from the third center point CP3 of the third identification part IA3 in the direction opposite to second direction D2. Accordingly, the third identification mark IM3 may indicate the direction opposite to second direction D2. Accordingly, the third identification mark IM3 may be identified as the number ‘9’.

In an embodiment, the fourth identification mark IM4 may be disposed on the fourth imaginary line IL4 extending from the fourth center point CP4 of the fourth identification part IA4 in the direction opposite to the fourth direction D4. Accordingly, the fourth identification mark IM4 may indicate the direction opposite to the fourth direction D4. Accordingly, the fourth identification mark IM4 may be identified as the number ‘8’.

As a result, the number ‘2’ indicated by the first identification mark IM1, the number ‘1’ indicated by the second identification mark IM2, the number ‘9’ indicated by the third identification mark IM3, and the number ‘8’ indicated by the fourth identification mark IM4 may be combined so that the identification pattern IP may be recognized as the identification number having four-digit.

For example, according to the order in which the first to fourth identification marks IM1, IM2, IM3, and IM4 are arranged along the first direction D1, the identification pattern IP defined by the first to fourth identification marks IM1, IM2, IM3, and IM4 may be recognized as an identification number of ‘2198’. However, the present inventive concept is not necessarily limited thereto, and the numbers indicated by each of the first to fourth identification marks IM1, IM2, IM3, and IM4 may be combined with each other in various orders.

In addition, detailed descriptions are omitted, but each of the identification patterns IP corresponding to the transfer lines shown in FIG. 2 may be recognized as an identification number derived by the same rule as the above-described rule.

Meanwhile, in FIG. 2, the transfer line FL is illustrated as including four identification parts and three connection parts, but this is only an example, and the number of the identification part and the number of the connection part included in the transfer line FL may be variously changed.

According to embodiments, the identification pattern IP for indicating the position and/or order of the transfer line FL may be defined from the identification mark having a simple shape. Accordingly, without forming an additional pattern indicating the transfer line that includes numbers corresponding to the transfer line FL (e.g., in the separation space SS) or changing a distance between the transfer lines, the position and/or order of the transfer line FL may be determined. Accordingly, a structure of the display device DD may be simplified, and efficiency of a manufacturing process of the display device DD may be increased.

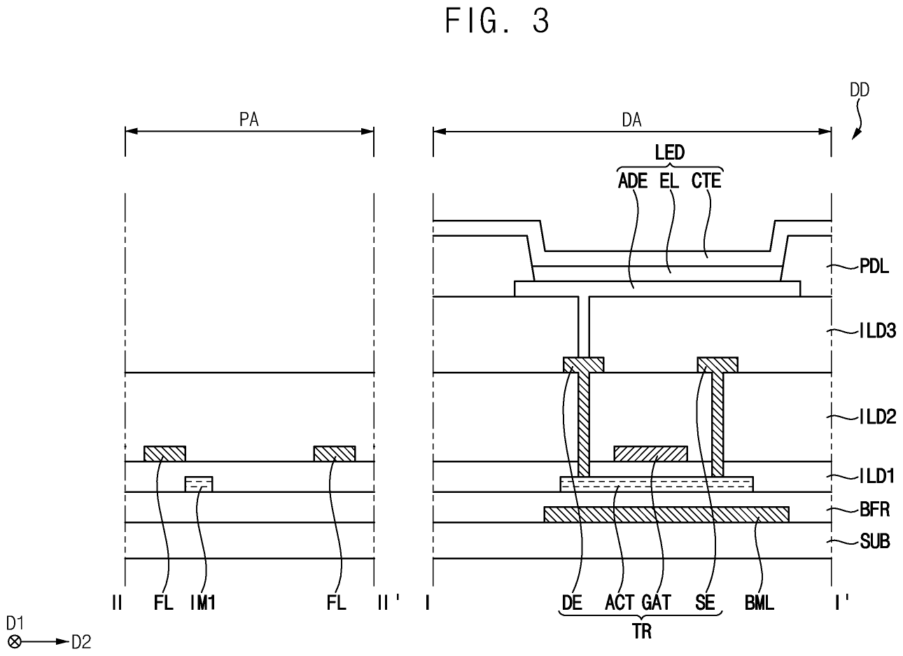

FIG. 3 is a cross-sectional view illustrating a cross section taken along line I-I′ of FIG. 1 and line II-II′ of FIG. 2 according to an embodiment. For example, FIG. 3 may be an enlarged cross-sectional view of a portion of the display area DA and a portion of the peripheral area PA of the display device DD.

Meanwhile, in FIG. 3, only a cross-sectional structure taken along a line passing through the first identification mark IM1 is shown for convenience of description. Cross-sectional structures taken along lines passing through identification marks included in the display device DD, including the second to fourth identification marks IM2, IM3, and IM4, may be substantially the same as the cross-sectional structure of FIG. 3.

Referring to FIG. 3, the display device DD according to an embodiment may include a substrate SUB, a lower metal layer BML, a buffer layer BFR, a first insulating layer ILD1, a transistor TR, a second insulating layer ILD2, a third insulating layer ILD3, a pixel defining layer PDL, a light emitting device LED, a transfer line FL, and a first identification mark IM1. The transistor TR may include an active pattern ACT, a gate electrode GAT, a source electrode SE, and a drain electrode DE. The light emitting device LED may include an anode electrode ADE, a light emitting layer EL, and a cathode electrode CTE.

The substrate SUB may include a transparent material or an opaque material. In an embodiment, examples of materials that can be used as the substrate SUB may include glass, quartz, plastic, or the like. These may be used alone or in combination with each other. In addition, the substrate SUB may be formed as a single layer or as multiple layers in combination with each other.

The lower metal layer BML may be disposed on the substrate SUB. In an embodiment, the lower metal layer BML may be formed of a metal, an alloy, a conductive metal oxide, a transparent conductive material, or the like. Examples of materials that can be used as the lower metal layer BML may include silver (Ag), an alloy containing silver, molybdenum (Mo), an alloy containing molybdenum, aluminum (Al), an alloy containing aluminum, and aluminum nitride (AlN), tungsten (W), tungsten nitride (WN), copper (Cu), nickel (Ni), chromium (Cr), chromium nitride (CrN), titanium (Ti), tantalum (Ta), platinum (Pt), There may be scandium (Sc), indium-tin oxide (ITO), indium-zinc oxide (IZO), or the like. These may be used alone or in combination with each other. In addition, the lower metal layer BML may be formed as a single layer or as multiple layers in combination with each other.

The buffer layer BFR may be disposed on the substrate SUB and cover the lower metal layer BML. In an embodiment, the buffer layer BFR may be entirely disposed on the display area DA and the peripheral area PA. The buffer layer BFR may include an inorganic insulating material.

The active pattern ACT may be disposed in the display area DA on the buffer layer BFR. In an embodiment, the active pattern ACT may include an oxide semiconductor, a silicon semiconductor, or an organic semiconductor. For example, the oxide semiconductor may include at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, or the like. These may be used alone or in combination with each other.

The first identification mark IM1 may be disposed in the peripheral area PA on the buffer layer BFR. In an embodiment, the first identification mark IM1 may be formed together with the active pattern ACT. In other words, the first identification mark IM1 may be disposed on the same layer as the active pattern ACT. In other words, the first identification mark IM1 may include the same material as the active pattern ACT. For example, the first identification mark IM1 may include the oxide semiconductor, the silicon semiconductor, or the organic semiconductor.

The first insulating layer ILD1 may be disposed on the buffer layer BFR and cover the active pattern ACT and the first identification mark IM1. The first insulating layer ILD1 may include an inorganic insulating material. In an embodiment, the first insulating layer ILD1 may be entirely disposed in the display area DA and the peripheral area PA on the buffer layer BFR.

The gate electrode GAT may be disposed in the display area DA on the first insulating layer ILD1. The gate electrode GAT may include a metal, an alloy, a conductive metal nitride, a conductive metal oxide, a transparent conductive material, or the like. Examples of materials that can be used as the gate electrode GAT may include gold (Au), silver (Ag), aluminum (Al), platinum (Pt), nickel (Ni), titanium (Ti), palladium (Pd), Magnesium (Mg), Calcium (Ca), Lithium (Li), Chromium (Cr), Tantalum (Ta), Tungsten (W), Copper (Cu), Molybdenum (Mo), Scandium (Sc), Neodymium (Nd), iridium (Ir), alloys containing aluminum, alloys containing silver, alloys containing copper, alloys containing copper, alloys containing molybdenum, aluminum nitride (AlN), tungsten nitride (WN), titanium nitride (TiN), Chromium Nitride (CrN), Tantalum Nitride (TaN), Strontium Ruthenium Oxide (SrRuO), Zinc Oxide (ZnO), Indium Tin Oxide (ITO), Tin Oxide (SnO), Indium Oxide (InO), Gallium Oxide (GaO), Indium zinc oxide (IZO), or the like. These may be used alone or in combination with each other. The gate electrode GAT may have a single-layer structure or a multi-layer structure including a plurality of conductive layers.

The transfer line FL may be disposed in the peripheral area PA on the first insulating layer ILD1. In an embodiment, the transfer line FL may be formed together with the gate electrode GAT. In other words, the transfer line FL may be disposed on the same layer as the gate electrode GAT. In other words, the transfer line FL may include the same material as the gate electrode GAT. For example, the transfer line FL may include a metal, an alloy, a conductive metal nitride, a conductive metal oxide, a transparent conductive material, or the like. However, the present inventive concept is not necessarily limited thereto, and the transfer line FL may be formed simultaneously with at least one of various conductive layers forming the transistor TR and the light emitting device LED.

The second insulating layer ILD2 may be disposed on the first insulating layer ILD1 and cover the gate electrode GAT and the transfer line FL. The second insulating layer ILD2 may include an inorganic insulating material. In an embodiment, the second insulating layer ILD2 may be entirely disposed in the display area DA and the peripheral area PA on the first insulating layer ILD1.

The source electrode SE and the drain electrode DE may be disposed on the second insulating layer ILD2. Each of the source electrode SE and the drain electrode DE may contact the active pattern ACT through contact holes. Based on a signal applied to the gate electrode GAT, the source electrode SE and the drain electrode DE may be electrically connected.

In an embodiment, each of the source electrode SE and the drain electrode DE may include a metal, an alloy, a conductive metal oxide, a transparent conductive material, or the like. Examples of materials that can be used as the source electrode SE and the drain electrode DE may include silver (Ag), an alloy containing silver, molybdenum (Mo), an alloy containing molybdenum, aluminum (Al), and aluminum. Alloy containing aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium-tin oxide (ITO), indium-zinc oxide (IZO), or the like. These may be used alone or in combination with each other.

The third insulating layer ILD3 may be disposed on the second insulating layer ILD2 and cover the source electrode SE and the drain electrode DE. The third insulating layer ILD3 may include an organic insulating material. In an embodiment, the third insulating layer ILD3 may be disposed in the display area DA on the second insulating layer ILD2.

The anode electrode ADE may be disposed on the third insulating layer ILD3. The anode electrode ADE may include a conductive material. The anode electrode ADE may be connected to the drain electrode DE through a contact hole formed in the third insulating layer ILD3. Accordingly, the anode electrode ADE may be electrically connected to the transistor TR.

The pixel defining layer PDL may be disposed on the anode electrode ADE. The pixel defining layer PDL may cover a peripheral portion of the anode electrode ADE and may define a pixel opening exposing a central portion of the anode electrode ADE. The pixel defining layer PDL may include an organic insulating material. In an embodiment, the pixel defining layer PDL may be disposed in the display area DA on the third insulating layer ILD3.

The light emitting layer EL may be disposed on the anode electrode ADE. In an embodiment, the light emitting layer EL may be disposed on the anode electrode ADE exposed by the pixel opening. However, the present inventive concept is not necessarily limited thereto, and in another embodiment, the light emitting layer EL may be disposed on the anode electrode ADE and the pixel defining layer PDL.

The cathode electrode CTE may be disposed on the light emitting layer EL and the pixel defining layer PDL. The light emitting layer EL may emit light based on a voltage difference between the anode electrode ADE and the cathode electrode CTE.

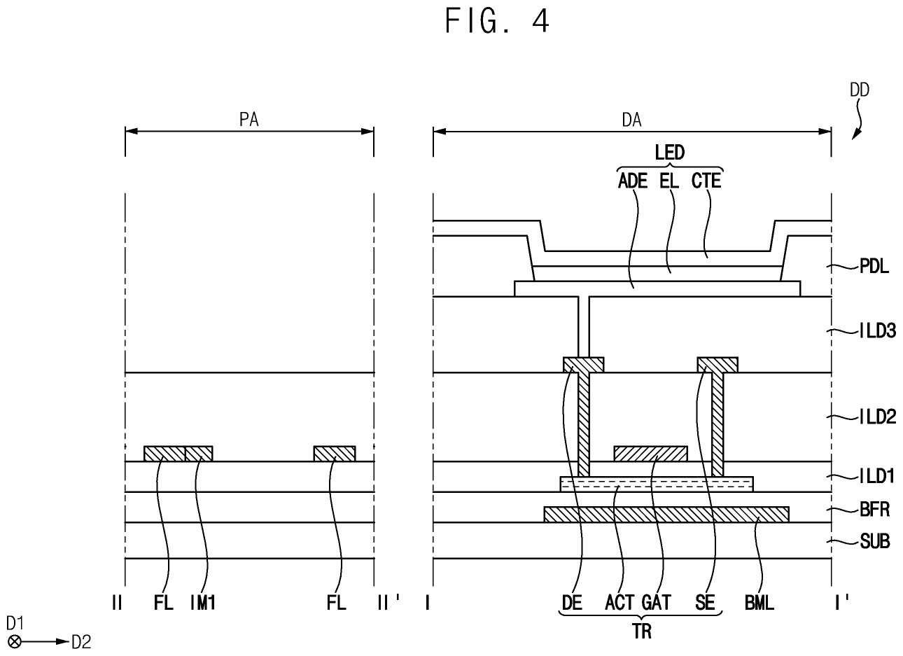

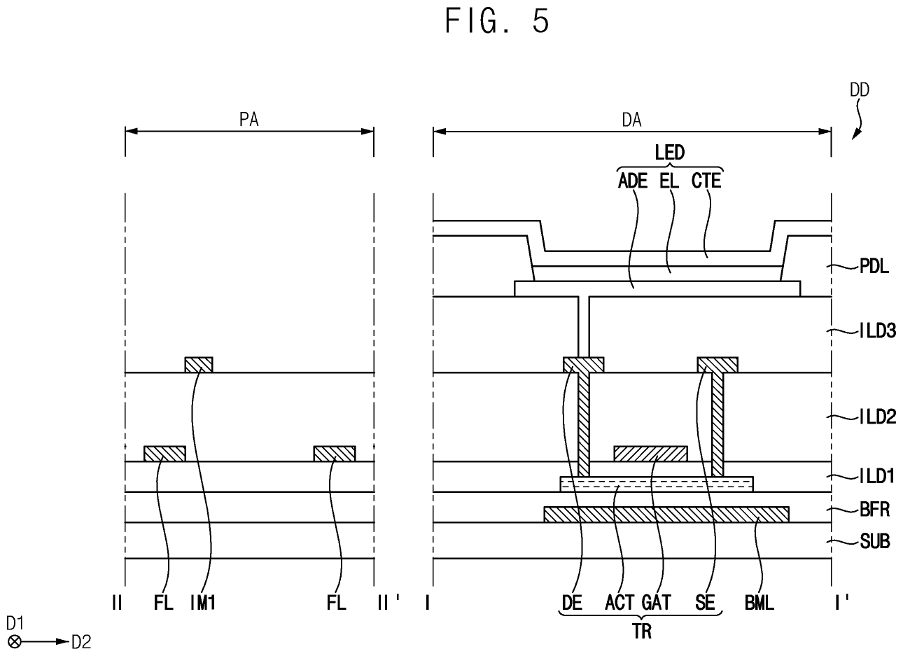

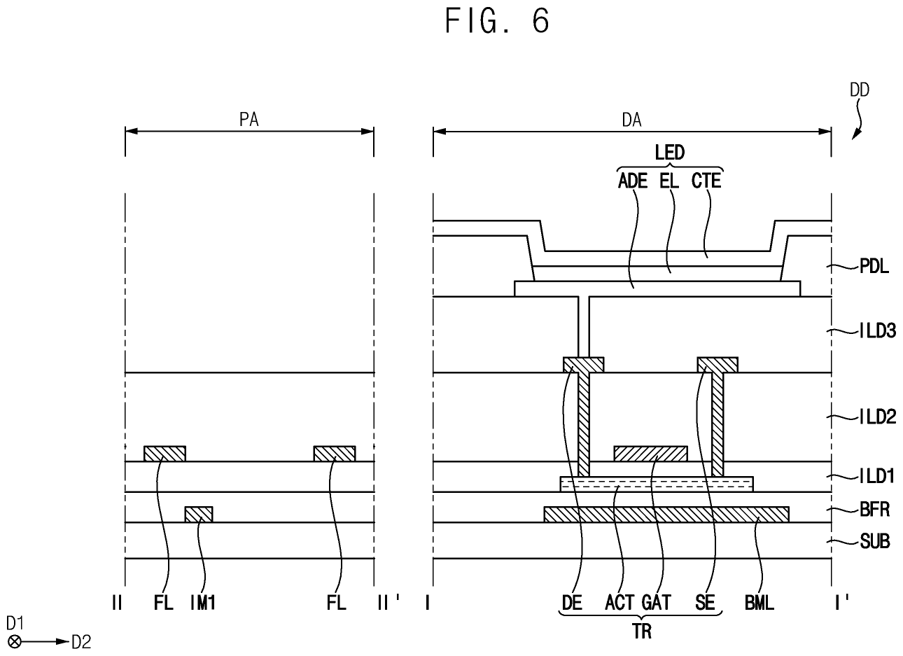

FIG. 4 is a cross-sectional view illustrating a cross section taken along line I-I′ of FIG. 1 and line II-II′ of FIG. 2 according to another embodiment. FIG. 5 is a cross-sectional view illustrating a cross section taken along line I-I′ of FIG. 1 and line II-II′ of FIG. 2 according to still another embodiment. FIG. 6 is a cross-sectional view illustrating a cross section taken along line I-I′ of FIG. 1 and line II-II′ of FIG. 2 according to still another embodiment.

Referring to FIG. 4, in another embodiment, the first identification mark IM1 may be disposed on the first insulating layer ILD1. In other words, the first identification mark IM1 may be disposed on the same layer as the gate electrode GAT. In other words, the first identification mark IM1 may be formed together with the gate electrode GAT and may include the same material as the gate electrode GAT.

Referring to FIG. 5, in still another embodiment, the first identification mark IM1 may be disposed on the second insulating layer ILD2. In other words, the first identification mark IM1 may be disposed on the same layer as the source electrode SE and the drain electrode DE. In other words, the first identification mark IM1 may be formed together with the source electrode SE and the drain electrode DE, and may include the same material as the source electrode SE and the drain electrode DE.

Referring to FIG. 6, in still another embodiment, the first identification mark IM1 may be disposed on the substrate SUB. In other words, the first identification mark IM1 may be disposed on the same layer as the lower metal layer BML. In other words, the first identification mark IM1 may be formed together with the lower metal layer BML and may include the same material as the lower metal layer BML.

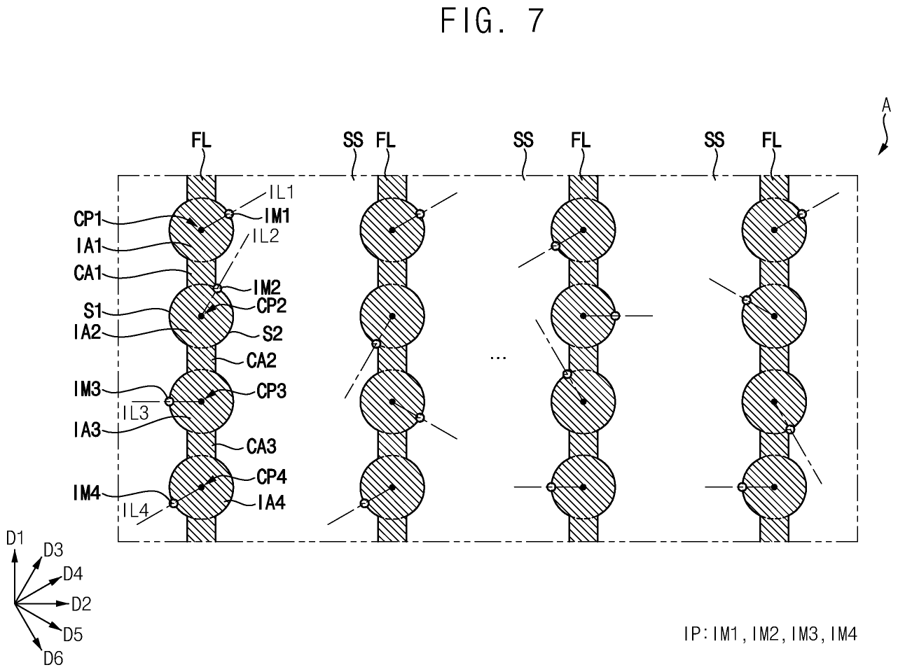

FIG. 7 is a plan view enlarged an area ‘A’ of FIG. 1 according to another embodiment.

Hereinafter, differences from the descriptions described with reference to FIGS. 1 and 2 will be mainly described, and repeated descriptions will be omitted or simplified.

Referring to FIG. 7, in an embodiment, a planar shape of the identification part and a planar shape of the connection part may be different from each other. Accordingly, the identification part and the connection part may be more clearly distinguished in a plan view. Accordingly, a direction in which the identification mark indicates may be identified more clearly.

Although the planar shape of the identification part is a circular shape and the planar shape of the identification mark is a circular shape in FIG. 7, the present inventive concept is not necessarily limited thereto. For example, the planar shape of the identification part may be a polygonal shape, and the planar shape of the identification mark may be a polygonal shape, a diamond shape, a track shape, an ellipse shape, or an arrow shape.

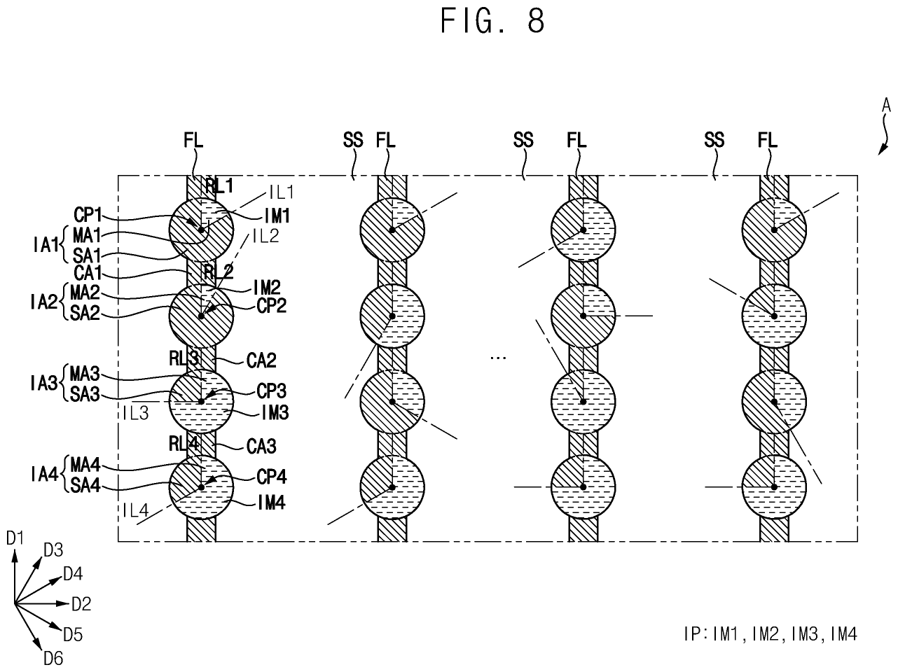

FIG. 8 is a plan view enlarged an area ‘A’ of FIG. 1 according to still another embodiment.

Hereinafter, differences from the descriptions described with reference to FIGS. 1 and 2 will be mainly described, and repeated descriptions will be omitted or simplified.

Referring to FIG. 8, in an embodiment, the first to fourth identification marks IM1, IM2, IM3, and IM4 may overlap the transfer line FL in a plan view. Specifically, each of the first to fourth identification marks IM1, IM2, IM3, and IM4 may overlap one of the first to fourth identification parts IA1, IA2, IA3, and IA4 of the transfer line FL in a plan view. For example, one identification mark among a plurality of identification marks overlapping the transfer line FL may overlap one identification part of the corresponding transfer line FL in a plan view.

For example, the first identification mark IM1 may overlap the first identification part IA1, the second identification mark IM2 may overlap the second identification part IA2, the third identification mark IM3 may overlap the third identification part IA3, and the fourth identification mark IM4 may overlap the fourth identification part IA4.

In an embodiment, each of the first to fourth identification parts IA1, IA2, IA3, and IA4 may be divided into a main area and a sub area by a reference line extending from the center point in the first direction D1 and an imaginary line extending from the center point in a direction other than the first direction D1.

In this case, the main area means an area extending from the reference line to the imaginary line in a clockwise direction, and the sub area means an area extending in a counterclockwise direction from the reference line to the imaginary line.

For example, the first identification part IA1 may be divided into a first main area MA1 and a first sub area SA1 by a first reference line RL1 extending from the first center point CP1 in the first direction D1 and a first imaginary line IL1 extending from the first center point CP1 in a direction other than the first direction D1.

The second identification part IA2 may be divided into a second main area MA2 and a second sub area SA2 by a second reference line RL2 extending from the second center point CP2 in the first direction D1 and a second imaginary line IL1 extending from the second center point CP2 in a direction other than the first direction D1.

The third identification part IA3 may be divided into a third main area MA3 and a third sub area SA3 by a third reference line RL3 extending from the third center point CP3 in the first direction D1 and a third imaginary line IL3 extending from the third center point CP1 in a direction other than the first direction D1.

The fourth identification part IA4 may be divided into a fourth main area MA4 and a fourth sub area SA4 by a fourth reference line RL4 extending from the fourth center point CP4 in the first direction D1 and a fourth imaginary line IL4 extending from the fourth center point CP4 in a direction other than the first direction D1.

In this case, the direction in which each of the first to fourth imaginary lines IL1, IL2, IL3, and IL4 extends from the corresponding center point may be substantially the same as the directions in which the first to fourth imaginary lines IL1, IL2, IL3, and IL4 extends described with reference to FIG. 2. Therefore, a detailed description thereof will be omitted.

In an embodiment, each of the first to fourth identification marks IM1, IM2, IM3, and IM4 may cover the main area of the corresponding identification part and expose the sub area of the corresponding identification part.

For example, the first identification mark IM1 may cover the first main area MA1 and expose the first sub area SA1. The second identification mark IM2 may cover the second main area MA2 and expose the second sub area SA1. The third identification mark IM3 may cover the third main area MA3 and expose the third sub area SA3. The fourth identification mark IM4 may cover the fourth main area MA4 and expose the fourth sub area SA4.

In an embodiment, each of the first to fourth identification marks IM1, IM2, IM3, and IM4 may be identified with one of integers from ‘0’ to ‘9’ according to a direction in which the imaginary line, which is a boundary of the main area, extends from the center point.

For example, when the imaginary line, which is the boundary of the main area corresponding to the identification mark, extends from the corresponding center point in the third direction D3, the identification mark may be identified as the number ‘1’.

When the imaginary line, which is the boundary of the main area corresponding to the identification mark, extends from the corresponding center point in the fourth direction D4, the identification mark may be identified as the number ‘2’.

When the imaginary line, which is the boundary of the main area corresponding to the identification mark, extends from the corresponding center point in the second direction D2, the identification mark may be identified as the number ‘3’.

When the imaginary line, which is the boundary of the main area corresponding to the identification mark, extends from the corresponding center point in the fifth direction D5, the identification mark may be identified as the number ‘4’.

When the imaginary line, which is the boundary of the main area corresponding to the identification mark, extends from the corresponding center point in the sixth direction D6, the identification mark may be identified as the number ‘5’.

When the imaginary line, which is the boundary of the main area corresponding to the identification mark, extends from the corresponding center point in the direction opposite to the sixth direction D6, the identification mark may be identified as the number ‘6’.

When the imaginary line, which is the boundary of the main area corresponding to the identification mark, extends from the corresponding center point in the direction opposite to the third direction D3, the identification mark may be identified as the number ‘7’.

When the imaginary line, which is the boundary of the main area corresponding to the identification mark, extends from the corresponding center point in the direction opposite to the fourth direction D4, the identification mark may be identified as the number ‘8’.

When the imaginary line, which is the boundary of the main area corresponding to the identification mark, extends from the corresponding center point in the direction opposite to the second direction D2, the identification mark may be identified as the number ‘9’.

When the imaginary line, which is the boundary of the main area corresponding to the identification mark, extends from the corresponding center point in the direction opposite to the fifth direction D5, the identification mark may be identified as the number ‘0’.

When the imaginary line, which is the boundary of the main area corresponding to the identification mark, extends from the corresponding center point in the direction opposite to the sixth direction D6, the identification mark may be identified as the number ‘6’.

Accordingly, the identification pattern IP corresponding to each transfer lines FL may be recognized as an identification number in which the numbers used to identify each of the first to fourth identification marks IM1, IM2, IM3, and IM4 adjacent to the corresponding transfer line FL are combined. Accordingly, the position and/or order of the transfer line FL may be determined from the identification pattern IP.

Hereinafter, a method of deriving the identification number will be described in more detail by taking the transfer line FL disposed at the leftmost of the transfer lines shown in FIG. 8 as an example.

In an embodiment, the first imaginary line IL1, which is a boundary of the first main area MA1 covered by the first identification mark IM1, may extend from the first center point CP1 in the fourth direction D4. Accordingly, the first identification mark IM1 may be identified as the number ‘2’.

In an embodiment, the second imaginary line IL2, which is a boundary of the second main area MA2 covered by the second identification mark IM2, may extend from the second center point CP2 in the third direction D3. Accordingly, the second identification mark IM2 may be identified as the number ‘1’.

In an embodiment, the third imaginary line IL3, which is a boundary of the third main area MA3 covered by the third identification mark IM3, may extend from the third center point CP3 in the direction opposite to the second direction D2. Accordingly, the third identification mark IM3 may be identified as the number ‘9’.

In an embodiment, the fourth imaginary line IL4, which is a boundary of the fourth main area MA4 covered by the fourth identification mark IM4, may extend from the fourth center point CP4 in the opposite to the fourth direction D4. Accordingly, the fourth identification mark IM4 may be identified as the number ‘8’.

As a result, the number ‘2’ indicated by the first identification mark IM1, the number ‘1’ indicated by the second identification mark IM2, the number ‘9’ indicated by the third identification mark IM3, and the number ‘8’ indicated by the fourth identification mark IM4 are combined, so that the identification pattern IP may be recognized as the identification number having four-digit.

For example, according to the order in which the first to fourth identification marks IM1, IM2, IM3, and IM4 are arranged along the first direction D1, the identification pattern IP defined from the first to fourth identification marks IM1, IM2, IM3, and IM4 may be recognized as an identification number of ‘2198’. However, the present inventive concept is not necessarily limited thereto, and the numbers signified by each of the first to fourth identification marks IM1, IM2, IM3, and IM4 may be combined with each other in various orders.

In addition, detailed descriptions are omitted, but each of the identification patterns IP corresponding to the transfer lines shown in FIG. 8 may be recognized as an identification number derived by the same rule as the above-described rule.

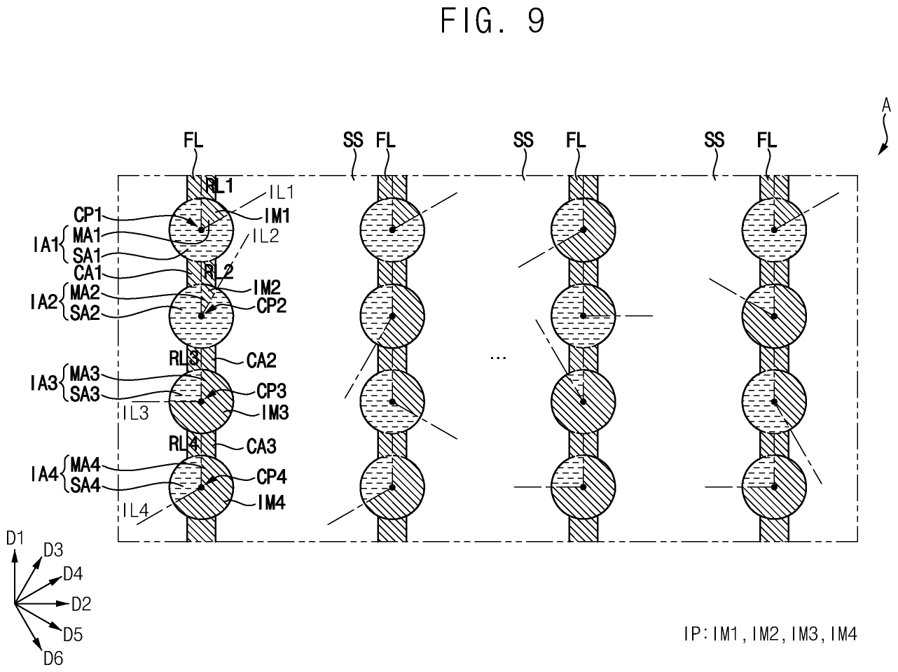

Meanwhile, in FIG. 8, the transfer line FL is illustrated as including four identification parts and three connection parts, but this is only an example, and the number of the identification part and the number of the connection part included in the transfer line FL may be variously changed. FIG. 9 is a plan view enlarged an area ‘A’ of FIG. 1 according to still another embodiment.

Hereinafter, differences from the descriptions described with reference to FIGS. 1, 2 and 8 will be mainly described, and repeated descriptions will be omitted or simplified.

Referring to FIG. 9, each of the first to fourth identification marks IM1, IM2, IM3, and IM4 may overlap one of the first to fourth identification parts IA1, IA2, IA3, and IA4 of the transfer line FL in a plan view. For example, one identification mark among a plurality of identification marks overlapping the transfer line FL may overlap one identification part of the corresponding transfer line FL in a plan view.

For example, the first identification mark IM1 may overlap the first identification part IA1, the second identification mark IM2 may overlap the second identification part IA2, the third identification mark IM3 may overlap the third identification part IA3, and the fourth identification mark IM4 may overlap the fourth identification part IA4.

In an embodiment, each of the first to fourth identification marks IM1, IM2, IM3, and IM4 may expose the main area of the corresponding identification part and cover the sub area of the corresponding identification part.

For example, the first identification mark IM1 may expose the first main area MA1 and cover the first sub area SA1. The second identification mark IM2 may expose the second main area MA2 and cover the second sub area SA1. The third identification mark IM3 may expose the third main area MA3 and cover the third sub area SA3. The fourth identification mark IM4 may expose the fourth main area MA4 and cover the fourth sub area SA4.

In this case, each of the first to fourth identification marks IM1, IM2, IM3, and IM4 may be identified with one of integers from ‘0’ to ‘9’ according to a direction in which the imaginary line, which is a boundary of the main area, extends from the center point.

Hereinafter, a method of deriving the identification number will be described in more detail by taking the transfer line FL disposed at the leftmost of the transfer lines shown in FIG. 9 as an example.

In an embodiment, the first imaginary line IL1, which is a boundary of the first main area MA1 exposed by the first identification mark IM1, may extend from the first center point CP1 in the fourth direction D4. Accordingly, the first identification mark IM1 may be identified as the number ‘2’.

In an embodiment, the second imaginary line IL2, which is a boundary of the second main area MA2 exposed by the second identification mark IM2, may extend from the second center point CP2 in the third direction D3. Accordingly, the second identification mark IM2 may be identified as the number ‘1’.

In an embodiment, the third imaginary line IL3, which is a boundary of the third main area MA3 exposed by the third identification mark IM3, may extend from the third center point CP3 in the direction opposite to the second direction D2. Accordingly, the third identification mark IM3 may be identified as the number ‘9’.

In an embodiment, the fourth imaginary line IL4, which is a boundary of the fourth main area MA4 exposed by the fourth identification mark IM4, may extend from the fourth center point CP4 in the opposite to the fourth direction D4. Accordingly, the fourth identification mark IM4 may be identified as the number ‘8’.

As a result, the number ‘2’ indicated by the first identification mark IM1, the number ‘1’ indicated by the second identification mark IM2, the number ‘9’ indicated by the third identification mark IM3, and the number ‘8’ indicated by the fourth identification mark IM4 are combined, so that the identification pattern IP may be recognized as the identification number having four-digit.

For example, according to the order in which the first to fourth identification marks IM1, IM2, IM3, and IM4 are arranged along the first direction D1, the identification pattern IP defined from the first to fourth identification marks IM1, IM2, IM3, and IM4 may be recognized as an identification number of ‘2198’. However, the present inventive concept is not necessarily limited thereto, and the numbers signified by each of the first to fourth identification marks IM1, IM2, IM3, and IM4 may be combined with each other in various orders.

In addition, detailed descriptions are omitted, but each of the identification patterns IP corresponding to the transfer lines shown in FIG. 9 may be recognized as an identification number derived by the same rule as the above-described rule.

Meanwhile, in FIG. 9, the transfer line FL is illustrated as including four identification parts and three connection parts, but this is only an example, and the number of the identification part and the number of the connection part included in the transfer line FL may be variously changed.

According to embodiments, the identification pattern IP for indicating the position and/or order of the transfer line FL may be defined from the identification mark having a simple shape. Accordingly, without forming an additional pattern indicating the transfer line that includes numbers corresponding to the transfer line FL (e.g., in the separation space SS) or changing a distance between the transfer lines, the position and/or order of the transfer line FL may be determined. Accordingly, a structure of the display device DD may be simplified, and efficiency of a manufacturing process of the display device DD may be increased.

The inventive concept should not be construed as being limited to the embodiments set forth herein. Rather, these embodiments are provided so that this disclosure will be thorough and complete and will fully convey the concept of the inventive concept to those skilled in the art.

While the inventive concept has been particularly shown and described with reference to embodiments thereof, it will be understood by those of ordinary skill in the art that various changes in form and details may be made therein without departing from the spirit or scope of the inventive concept as defined by the following claims.

What is claimed is:

1. A display device comprising:
a substrate including a display area and a peripheral area;
a light emitting device disposed in the display area on the substrate;
a transfer line disposed on the substrate, extending in a first direction, and including a plurality of identification parts arranged along the first direction and at least one connection part disposed between adjacent identification parts; and
a plurality of identification marks,
wherein each of the plurality of identification marks is disposed in an area corresponding to each identification part of the transfer line adjacent to the each identification part of the transfer line, and
wherein the each of the plurality of identification marks is disposed on an imaginary line extending from a center point of the corresponding identification part in a direction intersecting the first direction in a plan view.

2. The display device of claim 1, wherein the imaginary line extends from the center point of the identification part in a second direction perpendicular to the first direction, in a third direction inclined in a clockwise direction to the first direction and inclined in a counterclockwise direction to the second direction, in a fourth direction inclined in a clockwise direction to the third direction and inclined in a counterclockwise direction to the second direction, in a fifth direction inclined in a clockwise direction to the second direction, in a sixth direction inclined in a clockwise direction to the fifth direction, in a direction opposite to the first direction, in a direction opposite to the third direction, in a direction opposite to the fourth direction, in a direction opposite to the second direction, in a direction opposite to the fifth direction, or in a direction opposite to the sixth direction.

3. The display device of claim 2, wherein an angle between the third direction and the first direction is about 30 degrees.

4. The display device of claim 2, wherein an angle between the fourth direction and the first direction is about 60 degrees.

5. The display device of claim 2, wherein an angle between the fifth direction and the second direction is about 30 degrees.

6. The display device of claim 2, wherein an angle between the sixth direction and the second direction is about 60 degrees.

7. The display device of claim 2, wherein the transfer line includes:
a first side extending in the first direction; and
a second side extending in the first direction and facing the first side in the second direction, and
wherein the each of the plurality of identification marks is disposed adjacent to the first side or the second side in a plan view.

8. The display device of claim 7, wherein among the plurality of identification marks, an identification mark disposed on the imaginary line extending from the center point of the identification part in the direction opposite to the third direction, in the direction opposite to the fourth direction, in the direction opposite to the second direction, in the direction opposite to the fifth direction, or in the direction opposite to the sixth direction is disposed adjacent to the first side of the transfer line in a plan view.

9. The display device of claim 7, wherein among the plurality of identification marks, an identification mark disposed on the imaginary line extending from the center point of the identification part in the second direction, in the third direction, in the fourth direction, in the fifth direction, or in the sixth direction is disposed adjacent to the second side of the transfer line in a plan view.

10. The display device of claim 1, wherein a planar shape of each of the plurality of identification marks is a polygonal shape, a diamond shape, a circular shape, a track shape, an ellipse shape, or an arrow shape.

11. The display device of claim 1, wherein a planar shape of each of the plurality of identification parts is a polygonal shape or a circular shape.

12. The display device of claim 1, wherein a planar shape of the plurality of identification parts and a planar shape of the at least one connection part are different from each other.

13. The display device of claim 1, further comprising:
a transistor including an active pattern, a gate electrode, a source electrode, and a drain electrode sequentially disposed in the display area on the substrate, and
wherein the plurality of identification marks are disposed on the same layer as any one of the active pattern, the gate electrode, the source electrode, and the drain electrode.

14. The display device of claim 1, wherein the transfer line is connected to a data line providing a data voltage to a pixel structure disposed in the display area.

15. A display device comprising:
a substrate including a display area and a peripheral area;
a light emitting device disposed in the display area on the substrate;
a transfer line disposed on the substrate, extending in a first direction, and including a plurality of identification parts arranged along the first direction and at least one connection part disposed between adjacent identification parts; and
a plurality of identification marks,
wherein each of the plurality of identification marks is disposed in an area corresponding to each identification part of the transfer line,
wherein the each of the plurality of identification marks overlaps the corresponding identification part in a plan view,
wherein the each of the identification parts is divided into a main area and a sub area by a reference line extending from a center point of the each of the identification parts in the first direction and an imaginary line extending from the center point of the each of the identification parts in a direction intersecting the first direction, and
wherein each of the plurality of identification marks covers one of the main area and the sub area of the corresponding identification part and exposes a remaining area.

16. The display device of claim 15, wherein the imaginary line extends from the center point of the identification part in a second direction perpendicular to the first direction, in a third direction inclined in a clockwise direction to the first direction and inclined in a counterclockwise direction to the second direction, in a fourth direction inclined in a clockwise direction to the third direction and inclined in a counterclockwise direction to the second direction, in a fifth direction inclined in a clockwise direction to the second direction, in a sixth direction inclined in a clockwise direction to the fifth direction, in a direction opposite to the first direction, in a direction opposite to the third direction, in a direction opposite to the fourth direction, in a direction opposite to the second direction, in a direction opposite to the fifth direction, or in a direction opposite to the sixth direction.

17. The display device of claim 16, wherein an angle between the third direction and the first direction is about 30 degrees.

18. The display device of claim 16, wherein an angle between the fourth direction and the first direction is about 60 degrees.

19. The display device of claim 16, wherein an angle between the fifth direction and the second direction is about 30 degrees.

20. The display device of claim 16, wherein an angle between the sixth direction and the second direction is about 60 degrees.
